(19) United States
(12) Patent Application Publication
(10) Pub. No.: US 2001/0019274 A1
(43) Pub. Date: Sep. 6, 2001

(54) Current detecting circuit and current detecting method

(75) Inventor: Junichi Goto, Tokyo (JP)

Correspondence Address: OSTROLENK FABER GERB & SOFFEN, 1180 AVENUE OF THE AMERICAS, NEW YORK, NY, 100368403

(73) Assignee: NEC Corporation

(21) Appl. No.: 09/797,349

(22) Filed: Mar. 1, 2001

(30) Foreign Application Priority Data
Mar. 3, 2000 (JP) 2000-059235

(51) Int. Cl. G01R 27/26

(52) U.S. Cl. 324/678

(57) ABSTRACT

A capacitance (1) is charged by making a switching means (2) conductive and by shutting down the switching means (2), the capacitance (1) is discharged through a measuring object device (6). A voltage comparing means (3) detects that a voltage Vc of the capacitance (1) is lower than a reference voltage Vr and outputs a comparison result. Because the larger the discharge current, the shorter a time until the voltage Vc of the capacitance (1) drops below the reference voltage Vr is, the magnitude of current is evaluated depending on a length of voltage fall time Tf.

### BACKGROUND OF THE INVENTION

1. Field of the Invention

The present invention relates to a current detecting circuit and a current detecting method and more particularly to a circuit and method for detecting a micro current in an LSI.

2. Description of the Related Art

Measurement of insulation degree between transistors in an LSI, off-leak characteristic of transistor and nA or pA order current is an important work for determining whether or not a device technology or process technology for implementing that LSI is proper and improving those technologies.

Conventionally, a parameter analyzer has been widely used to measure such a micro current in the LSI and it is necessary to layout a special pad for connecting the parameter analyzer to a measuring object device within the LSI.

Such a method in which a wiring pattern which may generate a defect such as short or open is disposed within the LSI, a voltage is supplied to that pattern to measure a current by means of an LSI tester and then a short or open defect in the wiring is detected has been reported in “IEEE Proceedings of the 1995 international conference on microelectronic test structures, volume 8, March 1995, pp265-270”.

Because a pad necessary for measuring a current with a parameter analyzer as described above occupies an area of about 100 micron×100 micron, this area is so large when process rule is sub-micro order. This produces following problems.

To determine whether or not the quality of device technology or process technology is acceptable and to improve them, it is desirable that measuring object devices are distributed at a sufficient density in a wafer plane and distribution of current in that plane can be grasped. Because a pattern of the distribution in the plane is generated by each step of process, it is possible to estimate what step has a problem in that process from the pattern of the distribution. For this purpose, a means allowing a sufficient quantity of measuring object devices to be disposed in each chip and these plural currents to be measured efficiently in a short time is necessary. However, the 100-micron square pad has such a problem that by disposing a quantity thereof corresponding to plural measuring object devices, a required chip size is increased thereby increasing production cost of an LSI.

A method for detecting a wiring defect by combination of wiring pattern disposed in an LSI with an LSI tester aims at detecting wire short and open. Although this method is effective for the improvement of wiring process, it cannot contribute to improvement of MOS device production process in terms of degree of insulation between transistors, transistor off-leak characteristic and the like.

### SUMMARY OF THE INVENTION

A specific object of the present invention is to provide a method for obtaining electric characteristics of a device such as degree of insulation between transistors in an LSI, transistor off-leak characteristic and the like, which are important information at development stage of LSI production process technology.

Particularly, by achieving this method by combination of detecting circuits constructed in an LSI with an LSI tester, the distribution of above-mentioned electric characteristics in a wafer plane can be measured quickly. As a result, feedback information useful for improvement of device production process can be provided.

An LSI function test step currently carried out by using only an LSI tester is an ordinary work, and it is easy to incorporate the current detecting method of the present invention into this step. As a result, even in mass production stage, the distribution of electric characteristics of the device in wafer plane can be obtained, thereby making it possible to provide information useful for monitoring of production process and management of LSI production yield rate.

To achieve the above-noted object, the present invention has the following basic technical constitution.

Specifically, a first aspect of the present invention is a current detecting circuit comprising: a capacitor, a switching means, a voltage comparing means, a first current detecting terminal and a second current detecting terminal, wherein the switching means having a first switching terminal, a second switching terminal and a switching control terminal, the voltage comparing means having a first input terminal, a second input terminal, and a comparison result output terminal, the second switching terminal of the switching means, a first terminal of the capacitor and the first input terminal of the voltage comparing means being connected to the first current detecting terminal, and a second terminal of the capacitor being connected to the second current detecting terminal.

In a second aspect of the present invention, the switching means is a MOS transistor.

In a third aspect of the present invention, the switching means is either one of a PMOS transistor and an NMOS transistor.

In a fourth aspect of the present invention, an object device to be measured is connected between the first current detecting terminal and the second current detecting terminal.

In a fifth aspect of the present invention, part or all thereof is provided in an LSI.

In a sixth aspect of the present invention, the first current detecting terminal and the second current detecting terminal are connected to two arbitrary nodes provided in an LSI.

In a seventh aspect of the present invention, the first switching terminal of the switching means, the switching control terminal of the switching means and the second input terminal of the voltage comparing means is connected to an input buffer provided in an LSI, respectively, and the comparison result output terminal of the voltage comparing means is connected to an output buffer provided in the LSI.

An eighth aspect of the present invention is a method of detecting current of an object device to be measured by using a current detecting circuit comprising a capacitor, a switching means having a first switching terminal, a second switching terminal and a switching control terminal, a voltage comparing means having a first input terminal, a second input terminal to which a reference voltage is applied, and a comparison result output terminal, the second switching terminal of the switching means, a first terminal of the capacitor and the first input terminal of the voltage comparing means being connected to a first current detecting terminal, a second terminal of the capacitor being connected to a second current detecting terminal, and the object device is connected between the first current detecting terminal and the second current detecting terminal, the method comprising the steps of: applying a control voltage to the switching control terminal of the switching means so as to connect the first switching terminal to the second switching terminal electrically, charging the capacitor up to a prescribed voltage higher than the reference voltage through the switching means by applying a prescribed charging voltage to the first switching terminal of the switching means, shutting down the switching means after the charging is completed, comparing a voltage of the first current detecting terminal with the reference voltage by the voltage comparing means, at a predetermined time after a shut-down condition of the switching means started, and outputting a comparison result from the comparison result output terminal of the voltage comparing means.

### BRIEF DESCRIPTION OF THE DRAWINGS

FIG. 1 is a block diagram showing a structure of an embodiment of the present invention.

FIG. 2 is a schematic diagram showing a structure of a current detecting circuit of an embodiment of the present invention.

FIG. 3 is a timing chart for explaining an operation of the current detecting circuit of the embodiment of FIG. 2.

FIG. 4 is a schematic diagram showing the structure of a circuit that is a voltage comparing means in the current detecting circuit according to another embodiment of the present invention.

FIG. 5 is a schematic diagram showing the structure of an embodiment using a multiplicity of the current detecting circuits of the present invention.

FIG. 6 is a timing chart for explaining an operation of the embodiment shown in FIG. 5.

### DESCRIPTION OF THE PREFERRED EMBODIMENTS

The preferred embodiments of the present invention will be described in detail with reference to the accompanying drawing in order to clarify the above described and other objects, feature and advantages of the invention.

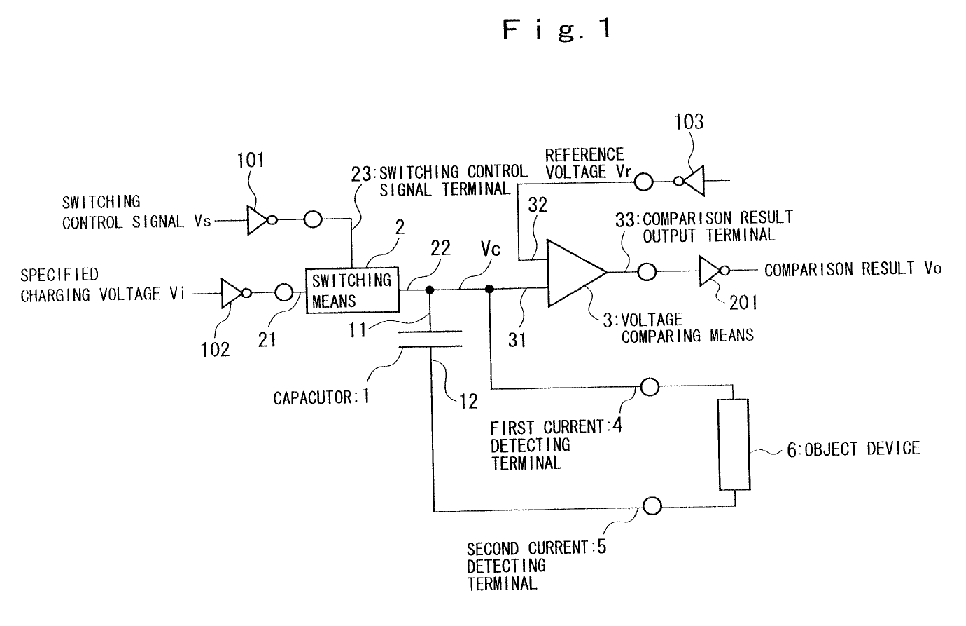

FIG. 1 shows a current detecting circuit according to an embodiment of the present invention.

This current detecting circuit comprises a capacitance 1, a switching means 2, a voltage comparing means 3, a first current detecting terminal 4 and a second current detecting terminal 5. An object device 6 for current detection is connected between the first current detecting terminal 4 and the second current detecting terminal 5.

If a switching control signal Vs supplied to the switching control signal terminal 23 is changed to a signal for making a switching means 2 conductive, the capacitance 1 is charged by a specified charging voltage Vi supplied to a second switching terminal 22 through the switching means 2, thereby the voltage of a node Vc rises. If the switching control signal Vs is changed to a signal for shutting down the switching means 2, the capacitance 1 discharges through the current detecting object device as a load resistor connected between the first current detecting terminal 4 and the second current detecting terminal 5. Therefore, the voltage of the node Vc drops.

The first voltage input terminal 31 of the voltage comparing means 3 is connected to the node Vc and on the other hand, a reference voltage Vr is supplied to a second voltage input terminal 32 of the voltage comparing means 3. Thus, the voltage comparing means 3 compares a magnitude of the voltage of the node Vc with that of the reference voltage Vr. Where the specified charging voltage Vi is larger than the reference voltage Vr (Vi>Vr). A comparison result is outputted as a comparison result Vo. For example, if the reference voltage Vr is larger than the voltage of the node Vc, the comparison result Vo outputs logical level “1” and in an inverse case, it outputs “0”.

An operation of this embodiment will be described below.

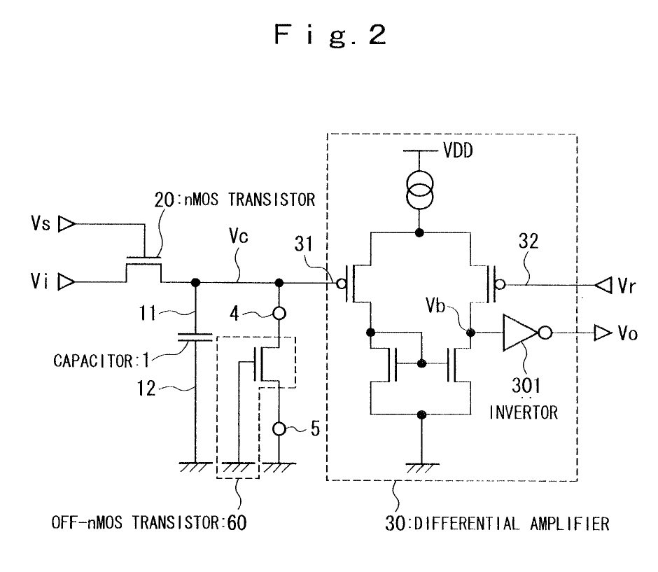

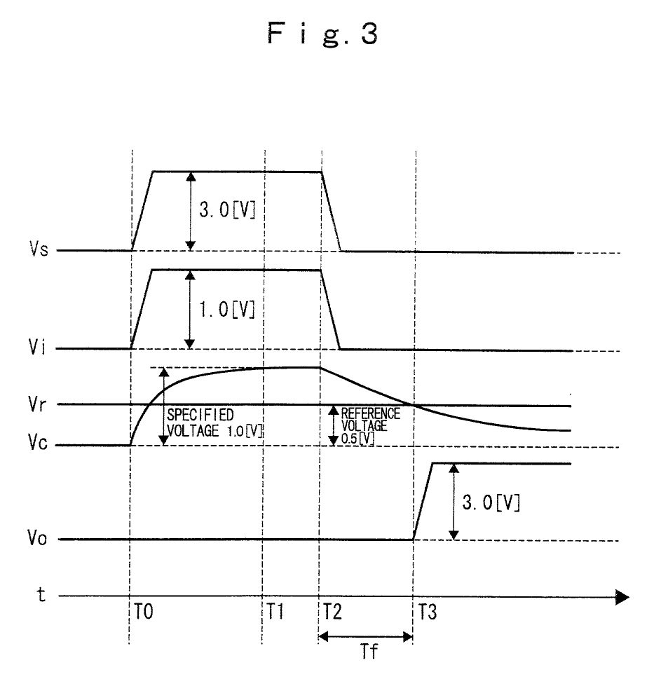

FIG. 2 shows an embodiment constructed using a MOS transistor as an object device of a current detecting circuit of a specific embodiment of the present invention. FIG. 3 shows a timing chart of each signal voltage of the current detecting circuit shown in FIG. 2. An operation of the current detecting circuit and a current detecting method of the present invention will be described with reference to these Figures.

Referring to FIG. 2, the switching means 2 and the voltage comparing means 3 of FIG. 1 are embodied by nMOS transistor 20 and a differential amplifier 30, respectively. The differential amplifier 30 has an invertor 301 at its output stage. The invertor 301 takes a role of a buffer for converting the voltage to a logical level of an appropriate shape for the LSI test to measure, because the voltage of the node Vb behaves as just like analog rather than in terms of logical level. The reason why an invertor that is a logical inverting circuit is employed is that this is the simplest buffer circuit. It is assumed that the capacitance 1 employs a gate capacity of the MOS transistor. In this embodiment, the object device is an off-nMOS transistor 60, gate terminal of which is always connected to the ground. Therefore, the current detecting circuit of this embodiment is an embodiment intended to detect off leak current of the nMOS transistor 60.

The second terminal 12 of the capacitance 1 and the second current detecting terminal 5 are connected to the ground. A switching control signal Vs, specified charging voltage Vi and reference voltage Vr are supplied from the LSI tester and a comparison result Vo is measured by the LSI tester. That is, the former three signals are supplied through an input buffers 101,102 and 103 of the LSI chip, respectively and the latter signal is outputted through an output buffer 201. In this embodiment, it is assumed that the LSI chip includes only one current detecting circuit shown in FIG. 2.

Names Vs, Vi, Vr, Vc, Vo of the respective signal waveforms of FIG. 3 correspond to switching control signal Vs, specified charging voltage Vi, reference voltage Vr, voltage of node Vc and comparison result Vo. Further, “t” indicates time.

As shown in FIG. 3, both the switching control signal Vs and specified charging voltage Vi are raised at t=T0. Because a power voltage of the MOS transistor and logical amplitude of this embodiment are assumed to be 3.0[V], the logical amplitude of the switching control signal Vs is specified to be 3.0[V] . This value is just a value under an embodiment.

The reason why the logical amplitude of the specified charging voltage Vi is specified to be 1.0[V] is that “a fall by Vt” (Vt is a threshold voltage) of the nMOS transistor 20 is taken into account when the specified charging voltage Vi is transmitted to the node Vc. That is, if a voltage lower than 3.0[V]−Vt is supplied to the specified charging voltage Vi when the switching control signal Vs=3.0[V] is supplied to a gate terminal 23, the “fall by Vt” does not occur, thereby a voltage of the specified charging voltage Vi is transmitted as the node voltage Vc as it is. This is a well-known fact to those skilled in the art. The transistor threshold voltage cannot be prevented from deviating by an influence of various changes of production process. Therefore, under a voltage setting that may generate the “fall by Vt”, a voltage after the node Vc is charged becomes uncertain, thereby inducing deterioration of accuracy in current detection after that. For the reason, it is necessary to set a voltage that never generates the “fall by Vt”. As long as the “fall by Vt” is not generated, the logical amplitude of the specified charging voltage Vi does not have to be 1.0[V] and this is only a value of an embodiment.

As both the switching control signal Vs and specified charging voltage Vi rise, a voltage of the node Vc connected to a terminal 11 of the capacitance 1 gradually rises. This voltage rise depends upon exponential function determined by a time constant having a resistance when the nMOS transistor 20 acts equivalently as a resistor and capacitance of the capacitance 1. The voltage of the node Vc continues to rise until it becomes the same voltage as the specified charging voltage Vi and then is saturated at that voltage. In FIG. 3, t=T1 indicates the saturation point. After that until t=T2, as a time margin, the switching control signal Vs and specified charging voltage Vi keep their logical amplitudes. If these voltages begin to fall at t=T2, the nMOS transistor 20 becomes off state and the capacitance 1 begins to discharge through the nMOS transistor 60 connected to the capacitance 1 in parallel. That is, the voltage of the node Vc begins to fall.

Because the node Vc is connected to a first voltage input terminal 31 of a differential amplifier 30 and the reference voltage Vr is supplied to a second voltage input terminal 32, if the voltage of the node Vc falls and becomes lower than the reference voltage Vr, the comparison result Vo is inverted from logical level “0” to logical level “1”=3.0[V] by an operation of the differential amplifier 30. In FIG. 3, t=T3 indicates its inversion time. A description of differential amplifier 30 is omitted because this circuit is a well known to those skilled in the art. Here, the reference voltage Vr is assumed to be 0.5[V] as an example.

Fall speed of the voltage of the node Vc depends upon a current flowing through the off-nMOS transistor 60. This current is a detection object of the current detecting circuit and current detecting method of the present invention. The larger the current becomes, the larger the fall speed of the voltage of the node Vc becomes, and vice versa. That is, as the detection object current increases, Tf=T3−T2 in FIG. 3 decreases so that the smaller the detection object current, the larger the Tf becomes. Therefore, by observing the Tf, it is possible to evaluate the magnitude of the detection object current.

In the case in which a current as small as possible is expected like the off-leak current in the transistor of this embodiment, if an allowable maximum current is predetermined and the capacitance of the capacitance 1, charging voltage Vi and reference voltage Vr are determined, Tf=T3−T2 corresponding to the allowable maximum value can be determined. That is, the Tf value can be obtained by regarding a device of current detection object equivalently as a resistor and assuming a well known action that the voltage of the node Vc falls following an exponential function by time constant having the capacitance and equivalent resistor.

If the Tf is determined, that is, T3 is determined, a comparison result Vo is observed using the LSI tester at t=T3. If the comparison result is logical level “0”, it is possible to determine that the detection object current is smaller than the maximum allowable current. Conversely if it is logical level “1”, it is possible to determine that the detection object current is larger than the maximum allowable current. In the former case, it is found that that device is produced to meet an expectation.

On the other hand, if a device of the current detection object cannot be regarded equivalently as a constant resistor, carrying out simulation using electric characteristic of that device can be considered, if possible. Alternatively, a following method can be considered. First, an appropriate specified charging voltage Vi and reference voltage Vr are set up. Naturally, the condition of Vi>Vr needs to be satisfied and for example, Vi=2Vr is set up like the above described embodiment. After that, the above embodiment is followed until discharging of the capacitance 1 begins. The LSI tester is actuated so that observation of the comparison result is carried out not only at only t=T3 but also at every time interval. This is repeated until the comparison result becomes logical level “1”. A difference of time from startup of discharge up to this point corresponds to Tf of FIG. 3. This measurement is carried out by the current detecting circuits of the present invention to all chips mounted on a wafer. Or the same measurement is carried out for all wafers in a lot. In this way, a histogram about the Tf can be obtained and by obtaining an average or standard deviation by statistical processing, an actually desirable Tf can be determined. Alternatively, it is possible to create a wafer map indicating distribution of Tf in the wafer in a function test. Or because some LSI testers have a function to search for signal transition points, it is possible to obtain the Tf by using it.

According to the method described above, a point in which the voltage of the node Vc becomes lower than the reference voltage Vr is searched. Alternatively, it is possible to observe the comparison result Vo at a fixed Tf against each voltage when the specified charging voltage Vi or reference voltage Vr is changed. For example, when the reference voltage Vr is fixed at 0.5[V] and the specified charging voltage Vi is decreased from 1.0[V] by 0.1[V] each, a comparison result Vo at t=T3 at each voltage is observed. Then, by depending on a voltage of the specified charging voltage Vi when a signal indicating that the node Vc becomes lower than the reference voltage Vr is outputted to the comparison result Vo, whether or not the current value is appropriate can be determined. A wafer map about this voltage value can be created. Further, it is also possible to change the reference voltage Vr while fixing the specified charging voltage Vi.

Although the above described matter takes a current expected to be as small as possible as an object, the current detecting circuit and current detecting method of the present invention can be applied to a case in which a current larger than a certain value is demanded.

If a device of current detection object can be regarded equivalently as a constant resistor, an allowable minimum current is determined in the same way as described above and the comparison result Vo is observed at time Tf determined thereby. If the comparison result is logical level “1”, it can be determined that that detection current is larger than the allowable minimum current, thereby indicating that the corresponding device is produced to meet an expectation and vice versa.

If a device of the current detection object cannot be regarded as a constant resistor, by considering statistical processing by histogram or wafer map, whether or not the detection object current is appropriate can be determined.

Meanwhile, the nMOS transistor 20 may allow a micro current to flow even if it is interrupted like a case in which the off-nMOS transistor 60 allows an off-leak current to flow. This may cause an error in determining the above Tf. A following countermeasure is taken to this problem. Because the nMOS transistor 20 and off-nMOS transistor 60 are connected in parallel as viewed from the capacitance 1, by replacing parallel combined resistance of those equivalent resistors with a resistance of the off nMOS transistor 60 used for determining the above Tf, it is possible to detect a micro current.

In the differential amplifier 30 or differential amplifier 35, even if there is some extent of a difference in voltage between its two inputs, the differential amplifier may determine that both the voltages are equal. This is so-called offset voltage. This is a factor for generating an error in measurement and its influence is desired to be removed as much as possible. Then, prior to the measurement, a following correction can be considered. With the nMOS transistor 20 conductive, the specified charging voltage Vi is fixed to 0.5[V] and the reference voltage Vr is set to initial voltage 0[V] and then gradually increased (for example, by 0.01[V]). Under the initial voltage, logical level “0” is outputted to the comparison result Vo and the reference voltage Vr is increased gradually so that it reaches logical level “1” near 0.5[V]. For example, if the value is 0.52[V], the offset voltage is 0.02[V]. A reference voltage Vr=0.52[V] is a virtual reference voltage. That is, the reference voltage Vr should be set to 0.52[V] in order to detect that the node Vc becomes lower than 0.5[V] by means of the differential amplifier 30.

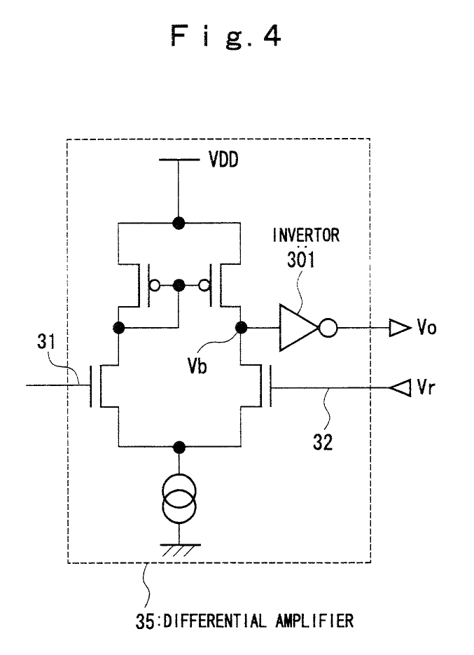

According to other embodiment of the present invention, the differential amplifier 35 shown in FIG. 4 may be used instead of the differential amplifier 30 shown in FIG. 2. The differential amplifier 30 and the differential amplifier 35 are circuits having complementary relation for each other and their qualitative operations are the same. Although additionally, various embodiments can be achieved, the differential amplifiers are well known to those skilled in the art, therefore, a detailed description thereof is omitted.

It is possible to replace an invertor 301 in each of the differential amplifiers 30, 35 with a non-inverting buffer. In this case, the output logical level of the comparison result Vo is reversed to that in the embodiment of the current detecting circuit shown in FIG. 2. As already described above, the role of the invertor 301 in the differential amplifier 30 or the non-inverting buffer in the differential amplifier 35 which is its substitutive means is to convert analog voltage at the node Vb of the differential amplifier 30 or the differential amplifier 35 to a voltage of logical level suitable for the LSI tester. Although the invertor is the simplest embodiment, well-known other various level converting circuits should be employed if a more accurate operation is expected.

According to still another embodiment, use of a pMOS transistor instead of the nMOS transistor 20 of FIG. 2 can be considered. In this case, the “fall by Vt” does not have to be considered.

According to further embodiment, use of an electromagnetic relay provided outside the LSI instead of the nMOS transistor 20 of FIG. 2 can be considered. In this case, although the electromagnetic relay needs to be provided on such a jig as a probing card of the LSI tester, this can provide an ideal interrupted condition, so that there is no error in determination of the Tf unlike the embodiment of the current detecting circuit shown in FIG. 2.

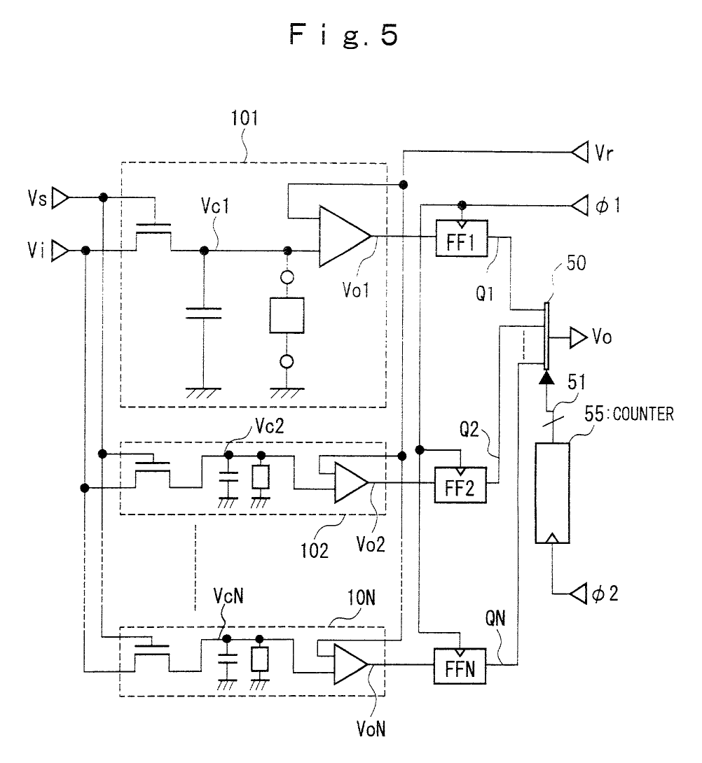

FIG. 5 shows still further embodiment. According to this embodiment, a multiplicity of the current detecting circuits is mounted on a single LSI chip. N current detecting circuits 101, 102, . . . 10N are mounted therein and each of them corresponds to the current detecting circuit of the embodiment shown in FIG. 2. The switching control signal Vs, specified charging voltage Vi and reference voltage Vr are supplied to those N current detecting circuits 101, 102, . . . ON from the LSI tester, respectively.

N flip-flops FF1, FF2, . . . FFN are mounted in the LSI chip and corresponding comparison results Vo1, Vo2, . . . VoN are inputted to those flip-flops.

A trigger φ1 is supplied in common to those flip-flops FF1, FF2, . . . FFN from the LSI tester and each flip-flop memorizes the corresponding comparison result at the rising edge of the trigger φ1.

Further, an N-input-1-output selector 50 and a counter 55 are mounted in the LSI chip. An output of each flip-flop is inputted to the selector 50. A select signal 51 for selecting one of N inputs to the selector 50 is supplied from the counter 55. The counter 55 carries out count operation at a rising edge of the trigger signal φ2 supplied from the LSI tester. The LSI tester observes the output of the selector 50 as comparison result Vo.

Although various flip-flop FF1, FF2, . . . FFN, selector 50 and counter 55 can be considered, these circuits are well known to those skilled in the art and therefore a description thereof is omitted.

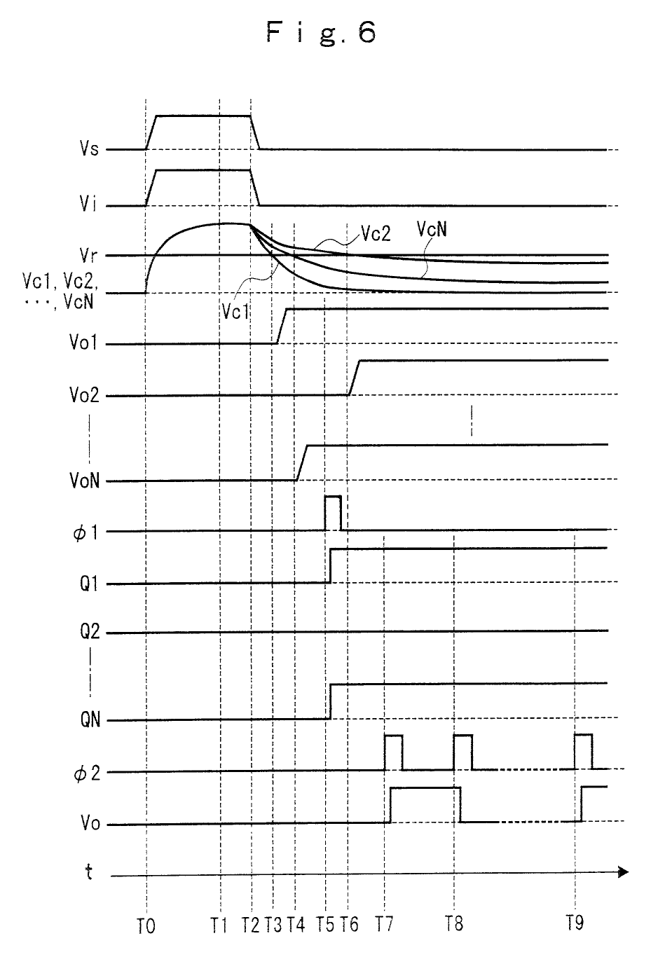

FIG. 6 shows a timing chart for explaining an operation of the embodiment of FIG. 5. Names of voltage waveforms in the timing chart of FIG. 6 indicate those at the same name points of FIG. 5. Although the timing chart of FIG. 3 up to t=T2 is the same as the embodiment of FIG. 2, in discharge from the capacitance within each current detecting circuit, the speed of voltage fall differs as shown by each waveform of Vc1, Vc2, . . . VcN. First, Vc1 crosses the reference voltage Vr at t=T3, so that the comparison result Vo1 becomes logical level “1”. Subsequently, VcN crosses the reference voltage Vr at t=T4 so that the comparison result VoN becomes logical level “1”. Likewise, the comparison result Vo2 becomes logical level “1” at t=T6. On the other hand, the trigger signal φ1 is supplied to the flip-flop group at t=T5. As a result, the comparison results Vo1, Vo2, VoN are memorized and outputs Q1, Q2, . . . QN of each flip-flop become “1”, “0”, . . . “1”. In FIG. 6, t=T5 corresponds to t=T3 of the timing chart of FIG. 3, that is, a timing for the LSI tester to observe the comparison result Vo. This is a timing that should be determined preliminarily.

When the trigger signal φ2 is supplied to the counter 55 at t=T7, the counter 55 outputs the select signal 51 to the selector 50, thereby the selector 50 selects output Q1 of the flip-flop FF1. As a result, the selector 50 outputs comparison result Vo of logical level “1”. When the trigger signal φ2 is supplied to the counter 55 at t=T8 again, the selector 50 selects output Q2 of the flip-flop FF2 and the selector 50 outputs comparison result Vo of logical level “0”. Likewise, the selector 50 outputs comparison result Vo of logical level “1” at t=T9.

According to the embodiment shown in FIG. 5, a multiplicity of the current detecting circuits are mounted within the same LSI chip so that their results can be read out successively by means of the LSI tester. By providing the current detecting circuit at an appropriate position in the chip, device characteristic distribution in the chip can be obtained, so that it is possible to provide information useful for device development and process development.

As described above, according to the present invention, by measuring the magnitude of a current of detecting object as a length of discharge time of the capacitance, it is possible to measure micro currents that cannot be measured directly by means of an LSI tester only. As a result, current characteristics of the micro current in the LSI can be captured quickly. Further, the current characteristic distribution in a wafer plane or chip can be captured efficiently by operating the same LSI tester. Meanwhile, it is apparent that the present invention is not restricted to the respective embodiments described above and the respective embodiments may be modified appropriately within a technical philosophy of the present invention.

What is claimed is:

1. A current detecting circuit comprising: a capacitor, a switching means, a voltage comparing means, a first current detecting terminal and a second current detecting terminal, wherein
said switching means having a first switching terminal, a second switching terminal and a switching control terminal,
said voltage comparing means having a first input terminal, a second input terminal, and a comparison result output terminal,
said second switching terminal of said switching means, a first terminal of said capacitor and said first input terminal of said voltage comparing means being connected to said first current detecting terminal, and
a second terminal of said capacitor being connected to said second current detecting terminal.

2. A current detecting circuit according to claim 1, wherein said switching means is a MOS transistor.

3. A current detecting circuit according to claim 1, wherein said switching means is either one of a PMOS transistor and an NMOS transistor.

4. A current detecting circuit according to claim 1, wherein an object device to be measured is connected between said first current detecting terminal and said second current detecting terminal.

5. A current detecting circuit according to claim 1, wherein part or all thereof is provided in an LSI.

6. A current detecting circuit according to claim 1, wherein said first current detecting terminal and said second current detecting terminal are connected to two arbitrary nodes provided in an LSI.

7. A current detecting circuit according to claim 1, wherein said first switching terminal of said switching means, said switching control terminal of said switching means and said second input terminal of said voltage comparing means are connected to an input buffer provided in an LSI, respectively, and said comparison result output terminal of said voltage comparing means is connected to an output buffer provided in said LSI.

8. A method of detecting current of an object device to be measured by using a current detecting circuit comprising a capacitor, a switching means having a first switching terminal, a second switching terminal and a switching control terminal, a voltage comparing means having a first input terminal, a second input terminal to which a reference voltage is applied, and a comparison result output terminal, said second switching terminal of said switching means, a first terminal of said capacitor and said first input terminal of said voltage comparing means being connected to a first current detecting terminal, a second terminal of said capacitor being connected to a second current detecting terminal, and said object device to be measured is connected between said first current detecting terminal and said second current detecting terminal, said method comprising the steps of:
applying a control voltage to said switching control terminal of said switching means so as to connect said first switching terminal of said switching means to said second switching terminal thereof electrically,
charging said capacitor up to a prescribed voltage higher than said reference voltage through said switching means by applying a prescribed charging voltage to said first switching terminal of said switching means,
shutting down said switching means after said charging is completed,
comparing a voltage of said first current detecting terminal with said reference voltage by said voltage comparing means, at a predetermined time after a shut-down condition of said switching means started, and
outputting a comparison result from said comparison result output terminal of said voltage comparing means.
